(19) United States
(12) Patent Application Publication
(10) Pub. No.: US 2010/0018135 A1
(43) Pub. Date: Jan. 28, 2010

(54) Rooftop photovoltaic systems

(75) Inventors: Steven Croft, Menlo Park, CA (US); William Sanders, Mountian View, CA (US); Ben Tarbell, Palo Alto, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 12/461,889

(22) Filed: Aug. 27, 2009

Related U.S. Application Data
(62) Division of application No. 11/777,397, filed on Jul. 13, 2007.

(51) Int. Cl. E04D 13/18; H01L 31/042

(52) U.S. Cl. 52/173.3; 136/244

(57) ABSTRACT

Provided are easy-to-install rooftop photovoltaic systems. One rooftop photovoltaic system includes a roofing material piece, a photovoltaic module disposed on the roofing material piece and an inverter configured to convert DC from the photovoltaic module into AC. Another rooftop photovoltaic system includes at least one active unit including one or more photovoltaic modules each including photovoltaic cells shaped as shingles to provide a roofing material appearance; and one or more inactive units having the roofing material appearance.

### CROSS-REFERENCE TO RELATED APPLICATIONS

This application is a Divisional of U.S. application Ser. No. 11/777,397, filed Jul. 13, 2007, which is incorporated herein by reference in its entirety.

### FIELD

The present invention relates in general to the field of photovoltaics and more specifically to rooftop photovoltaic systems and methods of making and using thereof.

### BACKGROUND

Rooftop installation of currently available commercial photovoltaic systems is often complicated and requires a great number of electrical connections to be made by installation technicians/electricians.

Thus, a need exists to develop rooftop photovoltaic systems that are easy to install and require a minimal number of electrical connections during the installation.

### SUMMARY

According to the first embodiment, a rooftop photovoltaic system comprises one or more strings, each comprising a roofing material piece and one or more units that each comprises a photovoltaic module disposed on the roofing material piece and an inverter configured to convert DC from the photovoltaic module into AC.

According to the second embodiment, a rooftop photovoltaic system comprises at least one active unit comprising one or more photovoltaic modules each comprising photovoltaic cells shaped as shingles to provide a roofing material appearance; and one or more inactive units having the roofing material appearance.

### DRAWINGS

FIG. 1 schematically depicts a photovoltaic module that includes two photovoltaic cells and a flexible collector-connector.

FIGS. 2A and 2B schematically depict a photovoltaic module that includes two photovoltaic cells and a flexible collector-connector.

FIG. 3 schematically depicts a photovoltaic module that includes a plurality of photovoltaic cells.

FIG. 4 is a photograph of a flexible Cu(In,Ga)Se₂ (CIGS) cell formed on flexible stainless steel substrate.

FIG. 5 is a photograph illustrating a flexible nature of CIGS cell formed on flexible stainless steel substrate.

FIG. 6 schematically depicts a photovoltaic module comprising photovoltaic cells shaped as shingles.

FIG. 7 schematically depicts a rooftop photovoltaic system that has an inverter attached to each of photovoltaic modules of the system.

FIG. 8A schematically depicts a rooftop photovoltaic system according to one of the embodiments.

FIG. 8B schematically depicts a rooftop photovoltaic system that has inactive units (“edge tie-ins”), which together with photovoltaic modules of the system match a shape of the roof on which the system is installed.

### DETAILED DESCRIPTION

Unless otherwise specified “a” or “an” refer to one or more.

The following related patent applications, which are incorporated herein by reference in their entirety, can be useful for understanding and practicing the invention:
1) U.S. patent application Ser. No. 11/451,616 “Photovoltaic Module with Integrated Current Collection and Interconnection” filed Jun. 13, 2006 to Hachtmann et al.;
2) U.S. patent application Ser. No. 11/451,605 “Photovoltaic Module with Insulating Interconnect Carrier” filed Jun. 13, 2006 to Hachtmann et al.;
3) U.S. patent application Ser. No. 11/639,428 “Photovoltaic Module Utilizing a Flex Circuit for Reconfiguration” filed Dec. 15, 2006 to Dorn et al.;
4) US patent application titled “Photovoltaic Modules with Integrated Devices” to Croft et al. (Attorney Docket No. 075122-0108) filed on the same date herewith;
5) U.S. patent application Ser. No. 11/812,515 “Photovoltaic Module Utilizing an Integrated Flex Circuit and Incorporating a Bypass Diode” filed Jun. 19, 2007 to Paulson et al.
   The present inventors developed easy to install rooftop photovoltaic systems that can require a minimal amount of electrical connections during an installation.

According to the first embodiment, a rooftop photovoltaic system includes one or more strings, each comprising one or more units that each include a roofing material piece, a photovoltaic module disposed on the rooftop material piece and an inverter configured to convert DC from the photovoltaic module into AC.

According to the second embodiment, a rooftop photovoltaic system includes one or more active units such that each of the units comprises one or more photovoltaic modules comprising photovoltaic cells shaped as shingles to provide a roofing material appearance and one or more inactive units that have the same roofing material visual appearance.

### Photovoltaic Module

The photovoltaic modules used in the rooftop photovoltaic systems of the present invention can be photovoltaic modules of any type. In some embodiments, at least one of the photovoltaic modules can be a photovoltaic module that includes at least two photovoltaic cells and a collector-connector. As used herein, the term “module” includes an assembly of at least two, and preferably three or more electrically interconnected photovoltaic cells, which may also be referred to as “solar cells”. The “collector-connector” is a device that acts as both a current collector to collect current from at least one photovoltaic cell of the module, and as an interconnect which electrically interconnects the at least one photovoltaic cell with at least one other photovoltaic cell of the module. In general, the collector-connector takes the current collected from each cell of the module and combines it to provide a useful current and voltage at the output connectors of the module.

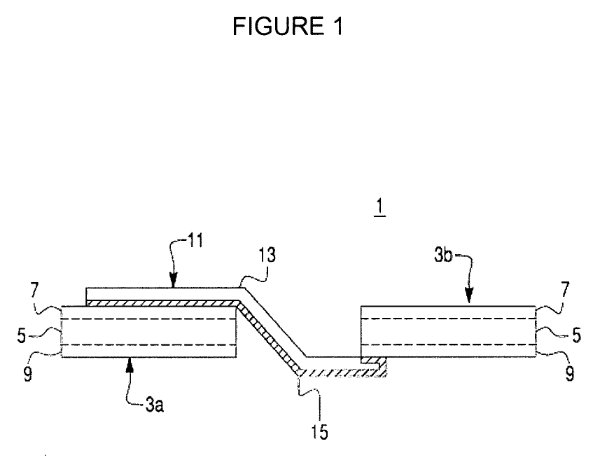

FIG. 1 schematically illustrates a module 1 that includes first and second photovoltaic cells 3a and 3b and a collector-connector 11. It should be understood that the module 1 may contain three or more cells, such as 3-10,000 cells for example. Preferably, the first 3a and the second 3b photovoltaic cells are plate shaped cells which are located adjacent to each other, as shown schematically in FIG. 1. The cells may have a square, rectangular (including ribbon shape), hexagonal or other polygonal, circular, oval or irregular shape when viewed from the top.

Each cell 3a, 3b includes a photovoltaic material 5, such as a semiconductor material. For example, the photovoltaic semiconductor material may comprise a p-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as CIGS/CdS heterojunction, for example. Each cell 3a, 3b also contains front and back side electrodes 7, 9. These electrodes 7, 9 can be designated as first and second polarity electrodes since electrodes have an opposite polarity. For example, the front side electrode 7 may be electrically connected to an n-side of a p-n junction and the back side electrode may be electrically connected to a p-side of a p-n junction. The electrode 7 on the front surface of the cells may be an optically transparent front side electrode which is adapted to face the Sun, and may comprise a transparent conductive material such as indium tin oxide or aluminum doped zinc oxide. The electrode 9 on the back surface of the cells may be a back side electrode which is adapted to face away from the Sun, and may comprise one or more conductive materials such as copper, molybdenum, aluminum, stainless steel and/or alloys thereof. This electrode 9 may also comprise the substrate upon which the photovoltaic material 5 and the front electrode 7 are deposited during fabrication of the cells.

The module also contains the collector-connector 11, which comprises an electrically insulating carrier 13 and at least one electrical conductor 15. The collector-connector 11 electrically contacts the first polarity electrode 7 of the first photovoltaic cell 3a in such a way as to collect current from the first photovoltaic cell. For example, the electrical conductor 15 electrically contacts a major portion of a surface of the first polarity electrode 7 of the first photovoltaic cell 3a to collect current from cell 3a. The conductor 15 portion of the collector-connector 11 also electrically contacts the second polarity electrode 9 of the second photovoltaic cell 3b to electrically connect the first polarity electrode 7 of the first photovoltaic cell 3a to the second polarity electrode 9 of the second photovoltaic cell 3b.

Preferably, the carrier 13 comprises a flexible, electrically insulating polymer film having a sheet or ribbon shape, supporting at least one electrical conductor 15. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating carrier 13 may also comprise any other electrically insulating material, such as glass or ceramic materials. The carrier 13 may be a sheet or ribbon which is unrolled from a roll or spool and which is used to support conductor(s) 15 which interconnect three or more cells 3 in a module 1. The carrier 13 may also have other suitable shapes besides sheet or ribbon shape.

The conductor 15 may comprise any electrically conductive trace or wire. Preferably, the conductor 15 is applied to an insulating carrier 13 which acts as a substrate during deposition of the conductor. The collector-connector 11 is then applied in contact with the cells 3 such that the conductor 15 contacts one or more electrodes 7, 9 of the cells 3. For example, the conductor 15 may comprise a trace, such as silver paste, for example a polymer-silver powder mixture paste, which is spread, such as screen printed, onto the carrier 13 to form a plurality of conductive traces on the carrier 13. The conductor 15 may also comprise a multilayer trace. For example, the multilayer trace may comprise a seed layer and a plated layer. The seed layer may comprise any conductive material, such as a silver filled ink or a carbon filled ink which is printed on the carrier 13 in a desired pattern. The seed layer may be formed by high speed printing, such as rotary screen printing, flat bed printing, rotary gravure printing, etc. The plated layer may comprise any conductive material which can by formed by plating, such as copper, nickel, silver, cobalt or their alloys. The plated layer may be formed by electroplating by selectively forming the plated layer on the seed layer which is used as one of the electrodes in a plating bath. Alternatively, the plated layer may be formed by electroless plating. Alternatively, the conductor 15 may comprise a plurality of metal wires, such as copper, aluminum, and/or their alloy wires, which are supported by or attached to the carrier 13. The wires or the traces 15 electrically contact a major portion of a surface of the first polarity electrode 7 of the first photovoltaic cell 3a to collect current from this cell 3a. The wires or the traces 15 also electrically contact at least a portion of the second polarity electrode 9 of the second photovoltaic cell 3b to electrically connect this electrode 9 of cell 3b to the first polarity electrode 7 of the first photovoltaic cell 3a. The wires or traces 15 may form a grid-like contact to the electrode 7. The wires or traces 15 may include thin gridlines as well as optional thick busbars or buslines, as will be described in more detail below. If busbars or buslines are present, then the gridlines may be arranged as The modules provide a current collection and interconnection configuration and method that is less expensive, more durable, and allows more light to strike the active area of the photovoltaic module than the prior art modules. The module provides collection of current from a photovoltaic (“PV”) cell and the electrical interconnection of two or more PV cells for the purpose of transferring the current generated in one PV cell to adjacent cells and/or out of the photovoltaic module to the output connectors. In addition, the carrier is may be easily cut, formed, and manipulated. In addition, when interconnecting thin-film solar cells with a metallic substrate, such as stainless steel, the embodiments of the invention allow for a better thermal expansion coefficient match between the interconnecting solders used and the solar cell than with traditional solder joints on silicon PV cells) In particular, the cells of the module may be interconnected without using soldered tab and string interconnection techniques of the prior art. However, soldering may be used if desired.

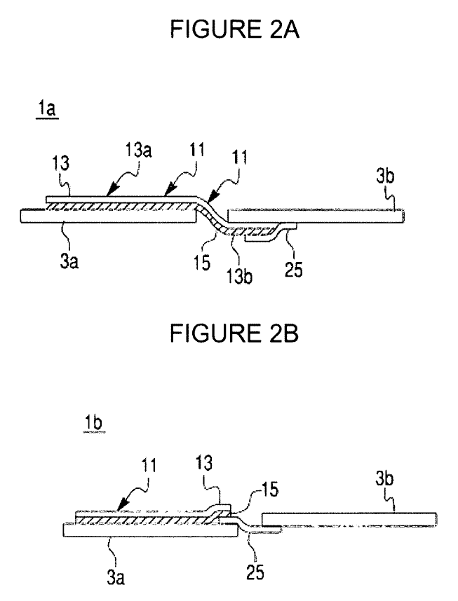

FIGS. 2A and 2B illustrate modules 1a and 1b, respectively, in which the carrier film 13 contains conductive traces 15 printed on one side. The traces 15 electrically contact the active surface of cell 3a (i.e., the front electrode 7 of cell 3a) collecting current generated on that cell 3a. A conductive interstitial material may be added between the conductive trace 15 and the cell 3a to improve the conduction and/or to stabilize the interface to environmental or thermal stresses. The interconnection to the second cell 3b is completed by a conductive tab 25 which contacts both the conductive trace 15 and the back side of cell 3b (i.e., the back side electrode 9 of cell 3b). The tab 25 may be continuous across the width of the cells or may comprise intermittent tabs connected to matching conductors on the cells. The electrical connection can be made with conductive interstitial material, conductive adhesive, solder, or by forcing the tab material 25 into direct intimate contact with the cell or conductive trace. Embossing the tab material 25 may improve the connection at this interface. In the configuration shown in FIG. 2A, the collector-connector 11 extends over the back side of the cell 3b and the tab 25 is located over the back side of cell 3b to make an electrical contact between the trace 15 and the back side electrode of cell 3b. In the configuration of FIG. 2B, the collector-connector 11 is located over the front side of the cell 3a and the tab 25 extends from the front side of cell 3a to the back side of cell 3b to electrically connect the trace 15 to the back side electrode of cell 3b.

In summary, in the module configuration of FIGS. 2A and 2B, the conductor 15 is located on one side of the carrier film 13. At least a first part 13a of carrier 13 is located over a front surface of the first photovoltaic cell 3a such that the conductor 15 electrically contacts the first polarity electrode 7 on the front side of the first photovoltaic cell 3a to collect current from cell 3a. An electrically conductive tab 25 electrically connects the conductor 15 to the second polarity electrode 9 of the second photovoltaic cell 3b. Furthermore, in the module 1a of FIG. 2A, a second part 13b of carrier 13 extends between the first photovoltaic cell 3a and the second photovoltaic cell 3b, such that an opposite side of the carrier 13 from the side containing the conductor 15 contacts a back side of the second photovoltaic cell 3b. Other interconnect configurations described in U.S. patent application Ser. No. 11/451,616 filed on Jun. 13, 2006 may also be used.

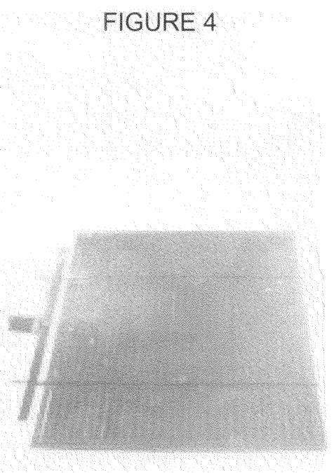

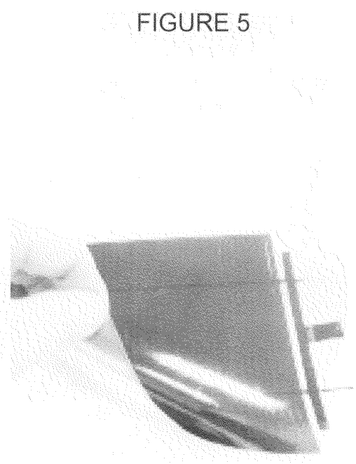

FIGS. 4 and 5 are photographs of flexible CIGS PV cells formed on flexible stainless steel substrates. The collector-connector containing a flexible insulating carrier and conductive traces shown in FIG. 2A and described above is formed over the top of the cells. The carrier comprises a PET/EVA co-extrusion and the conductor comprises electrolessly plated copper traces. FIG. 5 illustrates the flexible nature of the cell, which is being lifted and bent by hand.

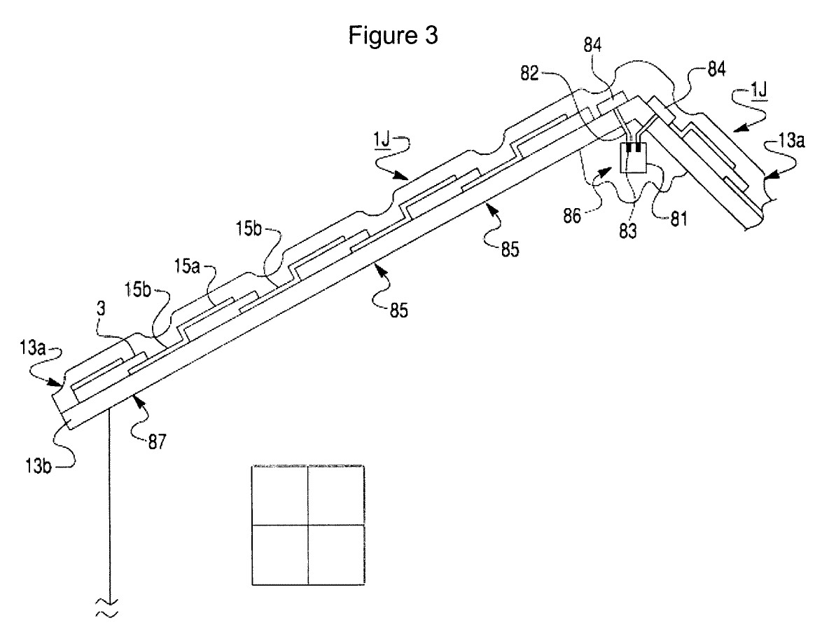

While the carriers 13 may comprise any suitable polymer materials, in one embodiment of the invention, the first carrier 13a comprises a thermal plastic olefin (TPO) sheet and the second carrier 13b comprises a second thermal plastic olefin membrane roofing material sheet which is adapted to be mounted over a roof support structure. Thus, in this aspect of the invention, the photovoltaic module 1j shown in FIG. 3 includes only three elements: the first thermal plastic olefin sheet 13a supporting the upper conductors 15a on its inner surface, a second thermal plastic olefin sheet 13b supporting the lower conductors 15b on its inner surface, and a plurality photovoltaic cells 3 located between the two thermal plastic olefin sheets 13a, 13b. The electrical conductors 15a, 15b electrically interconnect the plurality of photovoltaic cells 3 in the module, as shown in FIG. 3.

Preferably, this module 1j is a building integrated photovoltaic (BIPV) module which can be used instead of a roof in a building (as opposed to being installed on a roof) as shown in FIG. 3. In this embodiment, the outer surface of the second thermal plastic olefin sheet 13b is attached to a roof support structure of a building, such as plywood or insulated roofing deck. Thus, the module 1j comprises a building integrated module which forms at least a portion of a roof of the building.

If desired, an adhesive is provided on the back of the solar module 1j (i.e., on the outer surface of the bottom carrier sheet 13b) and the module is adhered directly to the roof support structure, such as plywood or insulated roofing deck. Alternatively, the module 1j can be adhered to the roof support structure with mechanical fasteners, such as clamps, bolts, staples, nails, etc. As shown in FIG. 3, most of the wiring can be integrated into the TPO back sheet 13b busbar print, resulting in a large area module with simplified wiring and installation. The module is simply installed in lieu of normal roofing, greatly reducing installation costs and installer markup on the labor and materials. For example, FIG. 3 illustrates two modules 1j installed on a roof or a roofing deck 85 of a residential building, such as a single family house or a townhouse. Each module 1j contains output leads 82 extending from a junction box 84 located on or adjacent to the back sheet 13b. The leads 82 can be simply plugged into existing building wiring 81, such as an inverter, using a simple plug-socket connection 83 or other simple electrical connection, as shown in a cut-away view in FIG. 3. For a house containing an attic 86 and eaves 87, the junction box 84 may be located in the portion of the module 1j (such as the upper portion shown in FIG. 3) which is located over the attic 86 to allow the electrical connection 83 to be made in an accessible attic, to allow an electrician or other service person or installer to install and/or service the junction box and the connection by coming up to the attic rather than by removing a portion of the module or the roof.

In summary, the module 1j may comprise a flexible module in which the first thermal plastic olefin sheet 13a comprises a flexible top sheet of the module having an inner surface and an outer surface. The second thermal plastic olefin sheet 13b comprises a back sheet of the module having an inner surface and an outer surface. The plurality of photovoltaic cells 3 comprise a plurality of flexible photovoltaic cells located between the inner surface of the first thermal plastic olefin sheet 13a and the inner surface of the second thermal plastic olefin sheet 13b. The cells 3 may comprise CIGS type cells formed on flexible substrates comprising a conductive foil. The electrical conductors include flexible wires or traces 15a located on and supported by the inner surface of the first thermal plastic olefin sheet 13a, and a flexible wires or traces 15b located on and supported by the inner surface of the second thermal plastic olefin sheet 13b. As in the previous embodiments, the conductors 15 are adapted to collect current from the plurality of photovoltaic cells 3 during operation of the module and to interconnect the cells. While TPO is described as one exemplary carrier 13 material, one or both carriers 13a, 13b may be made of other insulating polymer or non-polymer materials, such as EVA and/or PET for example, or other polymers which can form a membrane roofing material. For example, the top carrier 13a may comprise an acrylic material while the back carrier 13b may comprise PVC or asphalt material.

The carriers 13 may be formed by extruding the resins to form single ply (or multi-ply if desired) membrane roofing and then rolled up into a roll. The grid lines and busbars 15 are then printed on large rolls of clear TPO or other material which would form the top sheet of the solar module 1j. TPO could replace the need for EVA while doubling as a replacement for glass. A second sheet 13b of regular membrane roofing would be used as the back sheet, and can be a black or a white sheet for example. The second sheet 13b may be made of TPO or other roofing materials. As shown in FIG. 3, the cells 3 are laminated between the two layers 13a, 13b of pre-printed polymer material, such as TPO.

The top TPO sheet 13a can replace both glass and EVA top laminate of the prior art rigid modules, or it can replace the Tefzel/EVA encapsulation of the prior art flexible modules. Likewise, the bottom TPO sheet 13b can replace the prior art EVA/Tedlar bottom laminate. The module 1j architecture would consist of TPO sheet 13a, conductor 15a, cells 3, conductor 15b and TPO sheet 13b, greatly reducing material costs and module assembly complexity. The modules 1j can be made quite large in size and their installation is simplified. If desired, one or more luminescent dyes which convert shorter wavelength (i.e., blue or violet) portions of sunlight to longer wavelength (i.e., orange or red) light may be incorporated into the top TPO sheet 13a.

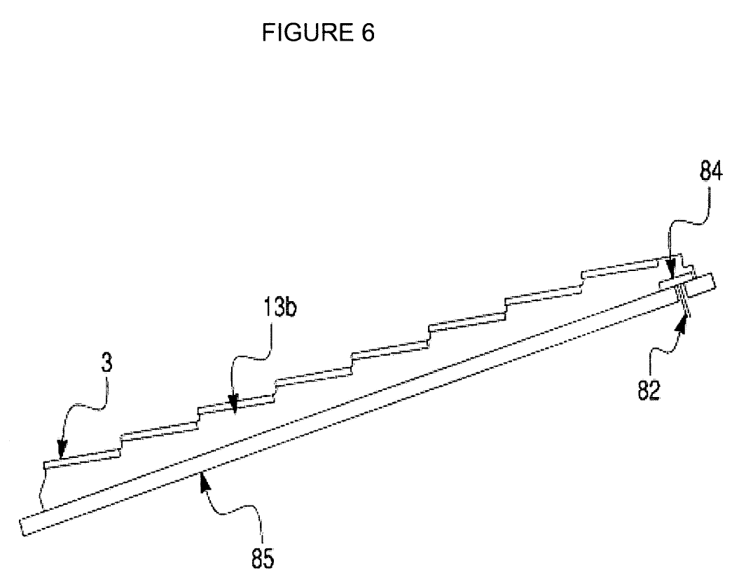

In some embodiments as shown in FIG. 6, the module 1k can contain PV cells 3, which are shaped as shingles to provide a conventional roofing material appearance, such as an asphalt shingle appearance, for a commercial or a residential building. This may be advantageous for buildings, such as residential single family homes and townhouses located in communities that require a conventional roofing material appearance, such as in communities that contain a neighborhood association with an architectural control committee and/or strict house appearance covenants or regulations, or for commercial or residential buildings in historic preservation areas where the building codes or other similar type regulations require the roof to have a shingle type appearance. The cells 3 may be located in stepped rows on the back sheet 13b, as shown in FIG. 6 (the optically transparent front sheet 13a is not shown for clarity) to give an appearance that the roof is covered with shingles. Thus, the back sheet 13b may have a stepped surface facing the cells 3. The cells in each row may partially overlap over the cells in the next lower row or the cells in adjacent rows may avoid overlapping as shown in FIG. 6 to increase the available light receiving area of each cell. The layered look of shingles could be achieved in the factory along with greatly simplified in the field wiring requirements to lower module and installation costs. The module containing photovoltaic cells shaped as shingles can be used in the rooftop photovoltaic system of the second embodiment

### Rooftop Photovoltaic System of the First Embodiment

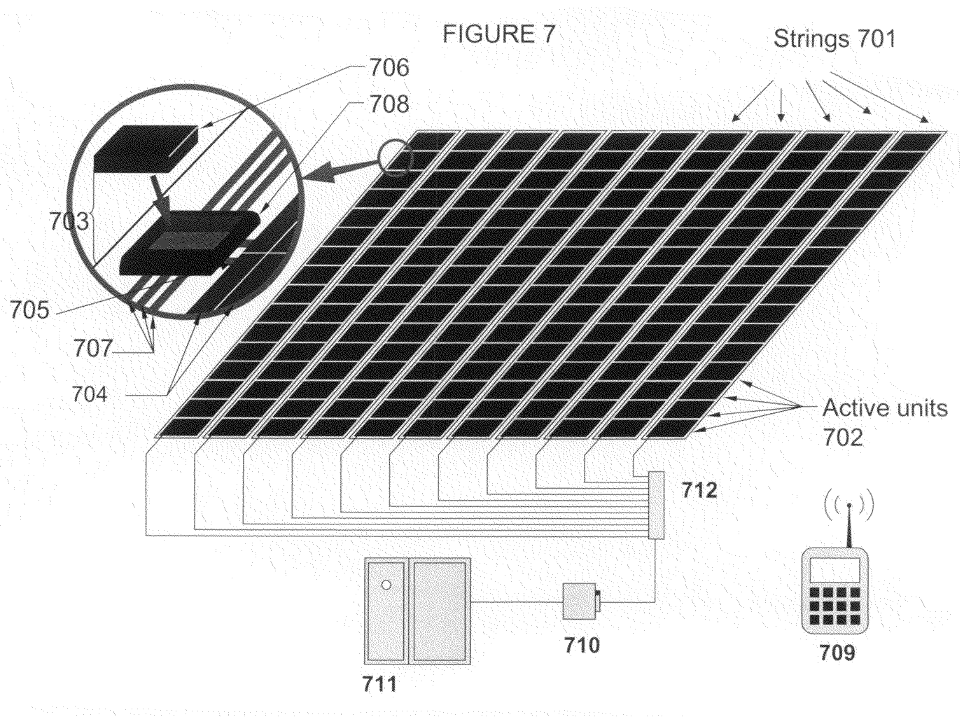

FIG. 7 illustrates a rooftop photovoltaic system according to the first embodiment. The rooftop photovoltaic system in FIG. 7 has eleven strings 701, each including a roofing material piece and sixteen active units 702. Each of the active units 702 includes a photovoltaic module disposed on the roofing material piece and an inverter that is configured to convert directed current (“DC”) from the photovoltaic module into alternating current (“AC”). Although FIG. 7 shows plural strings, in some cases, the rooftop photovoltaic system can have only one string. Similarly, although FIG. 7 shows plural active units on each of the strings, in some cases, a string of the photovoltaic system can include only one active unit.

Each of the photovoltaic modules of the active units 702 is preferably a flexible photovoltaic module comprising thin film photovoltaic cells, such as a photovoltaic module discussed above and in related U.S. patent applications Ser. Nos. 11/451,616; 11/451,605 and 11/639,428, which are each incorporated herein by reference in their entirety. The photovoltaic module(s) can disposed on the roofing material piece adjacent to each other as illustrated in FIG. 7. Preferably, the photovoltaic module(s) are laminated to the roofing material piece. Particular arrangement of the photovoltaic modules of the string on the roofing material piece can be different from the one in FIG. 7.

As noted above, the roofing material piece can comprise a roofing membrane material. Examples of roofing membrane materials include, but not limited to, the materials described above. Preferably, the roofing material piece has a shape of a roll or a ribbon.

The photovoltaic modules of the string can be factory interconnected, i.e. no electrical connections between the photovoltaic modules of the string is required to be performed during an installation of the photovoltaic system. The factory interconnection between the photovoltaic modules of the string can be accomplished via electrical connectors, such as busbars, integrated in the string or integrated with the roofing material piece of the string. Preferably, such integrated electrical connectors are AC busbars electrically connecting inverters associated with adjacent photovoltaic modules in the string. In the inset of FIG. 7, the AC busbars are designated as elements 707.

A location of the inverter of the active unit 702 relative to its respective photovoltaic module is not particularly restricted as long as the inverter is electrically connected to the module. For example, in the inset of FIG. 7, an inverter 703 is located adjacent to its respective photovoltaic module comprising photovoltaic cells 704. The inverter 703 is electrically connected to the module 704 via DC busbars 705, which are integrated with the string.

An inverter used in the photovoltaic system can be a detachable inverter, i.e. an inverter that can be easily detached from its respective photovoltaic module. For, example the inverter 703 shown in the inset of FIG. 7 is a detachable inverter that includes a detachable inverter element 706, such as a DC/AC inverter circuit, and an inverter housing/junction box 708. The inverter housing 708 is electrically connected via DC busbars 705 to the photovoltaic module. The inverter housing 708 also electrically contacts AC busbars 707. The inverter housing 708 without a detachable inverter element 706 is not active, i.e. it can not convert DC of the photovoltaic module into AC. The inverter element 706 is detachably located in the housing 708. For example, the inverter element 706 may be snap fitted (i.e., held by tension), bolted and/or clamped into the housing 708 and may be inserted and removed from the housing 708 with relative ease. Detachable inverters can be advantageous for safe shipping of the system, as the system can be shipped in an inactive state without the detachable inverter element(s) installed, and later activated by installing the detachable inverter element(s).

The photovoltaic system of the first embodiment may not require any DC installation connections, i.e. only AC connections should be made by during an installation of the photovoltaic system on a roof. Thus, a sheet which includes a plurality of photovoltaic modules, and where each module comprising photovoltaic cells 704, and a plurality of inverter housings 708 which contain factory prefabricated DC electrical connections (i.e., bus bars 705) to the plurality of photovoltaic modules is unrolled from a rolled position. The sheet is then installed on a roof of a structure, such as a house or building. The plurality of inverter housings 708 are then electrically connected to an AC electrical system 711 of the structure via the AC busbars 707. The detachable inverter elements 706 are then inserted into a respective inverter housing 708 before or after the AC connection of the housings 708.

A number of AC installation connections that are made during the installation of the photovoltaic system on the roof can be substantially equal to a number of the strings in the system. For example, if the photovoltaic system has only one string, then only one AC connection is required during the installation of the system on the roof. For the photovoltaic system illustrated in FIG. 7, which has eleven strings, a number of required AC installation connections can be eleven. AC connection to the string can be performed via AC outlet integrated in the string. In some cases, such AC outlet can include a top-mounted junction box included in one of the inverters of the string.

The photovoltaic system of the first embodiment can further include a central monitoring station 709, which comprises a computer, a logic circuit or another data processing device. The station 709 can be connected to one or more active units of the system via a wireless, wired or optical network. Preferably, the central monitoring station is connected to each of the one or more active units of the system. The central monitoring station can be connected can receive an information on parameters of any of the photovoltaic modules in the system from a sensor or sensors integrated in the module. Sensors that can be integrated in the module are disclosed, for example, in US patent application “Photovoltaic Modules with Integrated Devices” to Croft et al. filed on the same date herewith (Attorney Docket No. 075122-0108), which is incorporated by reference in its entirety. The central monitoring station can also be configured to communicate with one or more inverters of the system via a wireless, wired or optical network. Preferably, the central monitoring station can communicate with each of the inverters in the system. The monitoring station can be further connected via a wireless, wired or optical network to a personal computer.

In some embodiments, the rooftop photovoltaic system can include a smart AC disconnect 710. The smart AC disconnect can be integrated in the central monitoring station. The AC disconnect 710 can be electrically connected to a combiner box 712, which collects a power output from each of the strings of the system. If an information on a change of one or more parameter of one or more active units of the system reaches a central station, such as information regarding whether one or more strings becomes shaded by debris or tree branches, then the monitoring station can send a signal to the AC disconnect to electrically disconnect the affected string(s) of the system, such as the shaded string(s), from an external circuit 711 consuming electrical power from the system.

The rooftop photovoltaic system can installed on a roof using methods identical to the installation methods for the roofing material. The rooftop photovoltaic system of the first embodiment can be installed on a flat or nearly flat roof of a commercial, i.e. non-residential building. However, the system may also be installed on sloped residential and commercial building roofs.

In some cases, a roof, on which the photovoltaic system is installed, can have size constraints. For example, the roof can have a dimension that is shorter than a length of the string of the photovoltaic system. In such a case, the string can be cut between adjacent active units, i.e. between adjacent photovoltaic modules on the string. Cutting the string may result in an increased number of AC connections required during the installation of the system.

### Rooftop Photovoltaic System of the Second Embodiment

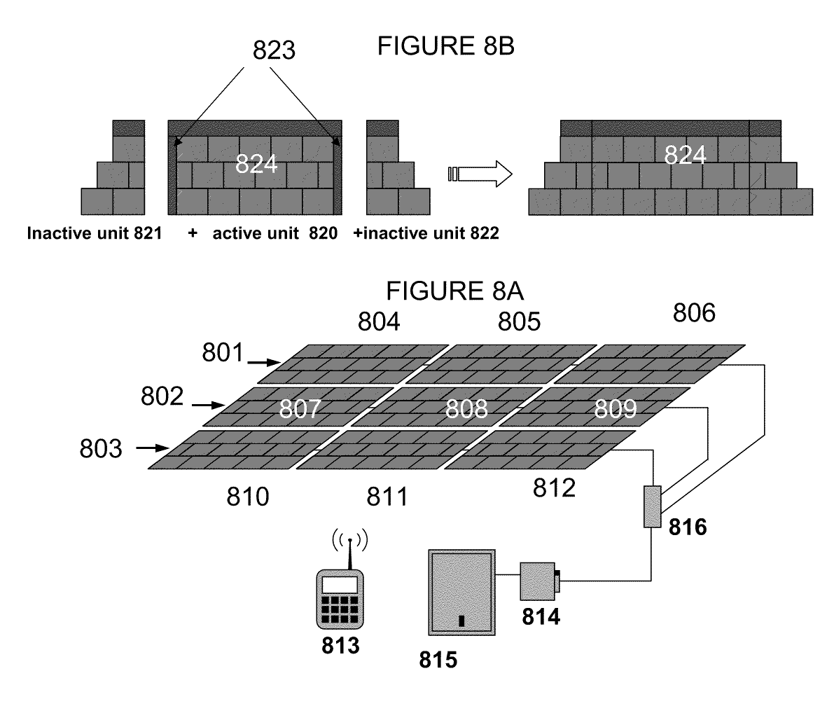

FIG. 8A illustrates a rooftop photovoltaic system according to the second embodiment, which includes active units 804, 805, 806, 807, 808, 809, 810, 811 and 812. Each of the active units includes one or more photovoltaic modules such that each of the modules comprises photovoltaic cells shaped as shingles. Each of the photovoltaic modules used in the photovoltaic system can be, for example, a photovoltaic module depicted in FIG. 6 and described above.

Each of the active units can include a back sheet on which the one or more photovoltaic modules of the unit are disposed. Preferably, the one or more photovoltaic modules of the active unit are laminated to the back sheet. The back sheet can comprise a roofing material, such as a roofing membrane material described above. The side of the back sheet opposite to the side on which the one or more photovoltaic modules are disposed, can have an adhesive layer, which can be used for adhering the active unit to the roof.

If the photovoltaic system includes plural active units, the active units can be organized or arranged in a variety of ways. For example, the active units can form one or more strings, within which the active units are electrically interconnected. The active units within a string can be factory interconnected, i.e. no electrical connection is required to be performed between the active units within the string. Active units in FIG. 8A are organized as follows: string 801 includes active units 804, 805 and 806, such that the active unit 804 is electrically connected to the active unit 805, which in turn is electrically connected to the active unit 806; string 802 includes active units 807, 808 and 809, such that the active unit 807 is electrically connected to the active unit 808, which in turn is electrically connected to the active unit 809; string 803 includes active units 810, 811 and 812, such that the active unit 810 is electrically connected to the active unit 811, which in turn is electrically connected to the active unit 812. When, the system includes plural strings, output from each of the string can be collected by a combiner box designated as 816 in FIG. 8A.

The rooftop photovoltaic system can include one or more inactive units, which do not have photovoltaic modules disposed on them. Preferably, such inactive roofing piece(s) have the same visual appearance of the active unit(s) of the system, i.e. the roofing material appearance produced by shingle-like shaped photovoltaic cells of the one or more photovoltaic modules. Preferably, the inactive unit(s) can comprise a roofing material such as asphalt roofing shingles or other suitable roofing shingle or tile material. As the active unit(s), the inactive unit(s) can be attached to a roof using adhesives or other attachment methods, such as thermal welding. The inactive unit(s) can have a shape that allows them together with the active unit(s) to match a shape of a roof, on which the photovoltaic system is installed. The inactive unit(s) can also used to facilitate the attachment of the active unit(s) of the system to a roof. For example, FIG. 8B shows an active unit 820, which has an area 824, where one or more photovoltaic modules are disposed. The one or more photovoltaic modules comprise photovoltaic cells shaped as shingles that produce a visual appearance of a conventional composition roofing material. Areas 823 of the unit 820 designate parts of the back sheet not covered by the one or more modules. Inactive units 821 and 822 have the same shingle like visual appearance as the patterned area 824 of the active unit 820. Together with the active unit 820 the inactive units 821 and 822 can match a shape of a roof, on which the system is installed. The inactive pieces 821 and 822 can facilitate binding of the active unit 820 to a normally constructed composition roof by overlapping areas 823 of the unit 820. The overlapping between the inactive units 821 and 822 and the active unit 820 can improve a waterproof protection of the roof.

Each of the photovoltaic modules of the system can include an inverter integrated with it similarly to the photovoltaic modules of the rooftop photovoltaic system of the first embodiment. Alternatively, the system can include an integrated voltage regulator which can track a performance of each of the photovoltaic modules in the system. For example, the voltage regulator can maximize power production of each of the modules. The integrated voltage regulator can be connected to a central inverter, which can convert DC produced by the photovoltaic modules of the system into AC. The central inverter can be a single stage inverter, i.e. an inverter that has a single stage that converts DC into AC and does not have a stage that amplifies DC.

Similarly to the first embodiment, the rooftop photovoltaic system of the second embodiment can include a central monitoring station designated as 813 in FIG. 8A, which can be connected to one or more photovoltaic modules of the system via a wireless, wired or optical connection. Preferably, the central monitoring station is connected to each of the one or more photovoltaic modules of the system. The central monitoring station can receive information on parameters of any of the photovoltaic modules in the system from a sensor or sensors integrated in the module. Sensors that can be integrated in the module are disclosed, for example, in US patent application “Photovoltaic Modules with Integrated Devices” to Croft et al. (Attorney Docket No. 075122-0108), which is incorporated by reference in its entirety. In some cases, the central monitoring station can be connected to a personal computer via a wireless, wired or optical connection.

In some embodiments, the rooftop photovoltaic system can include a smart AC disconnect 814 shown in FIG. 8A and as described in detail with respect to the first embodiment. The smart AC disconnect 814 can disconnect one or more strings 801-803 from the external circuit 815.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

What is claimed is:

1. A rooftop photovoltaic system, comprising:
at least one active unit comprising one or more photovoltaic modules each comprising photovoltaic cells shaped as shingles to provide a roofing material appearance; and
one or more inactive units having the roofing material appearance.

2. The rooftop photovoltaic system of claim 1, wherein:
each of the one or more photovoltaic modules comprises thin film photovoltaic cells; and
each of the one or more photovoltaic modules is a photovoltaic module comprising a first photovoltaic cell and a second photovoltaic cell and a collector-connector configured to collect current from the first photovoltaic cell and to electrically connect the first photovoltaic cell with the second photovoltaic cell.

3. The rooftop photovoltaic system of claim 1, wherein the one or more of photovoltaic modules are laminated to a membrane back sheet.

4. The rooftop photovoltaic system of claim 1, wherein each of the one or more photovoltaic modules comprises an integrated inverter.

5. The rooftop photovoltaic system of claim 1, further comprising a central inverter and an integrated voltage regulator configured to regulate voltage output of each of the one or more modules, wherein the voltage regulator is electrically connected to the central inverter.

6. The rooftop photovoltaic system of claim 1, wherein the at least one unit comprises a first unit and a second unit factory interconnected to the first unit.

7. The rooftop photovoltaic system of claim 1, further comprising:
a monitoring station connected to each of the one or more photovoltaic modules via wireless, wired or optical network; and
an AC disconnect.

8. The rooftop photovoltaic system of claim 1, wherein the one or more inactive units are configured to facilitate attachment of the at least one active unit to a roof.

9. The rooftop photovoltaic system of claim 1, wherein when the at least one active unit is installed on a roof, the one or more inactive units are configured to match a shape of the roof together with the at least one active unit.
